(19) United States
(12) Patent Application Publication
(10) Pub. No.: US 2024/0290586 A1
(43) Pub. Date: Aug. 29, 2024

(54) METHOD FOR FORMING THIN FILM AND APPARATUS FOR PROCESSING SUBSTRATE THEREFOR

(71) Applicant: WONIK IPS CO., LTD., Pyeongtaek-si Gyeonggi-do (KR)

(72) Inventors: Jae Hun LEE, Pyeongtaek-si Gyeonggi-do (KR); Kyoung Pil NA, Pyeongtaek-si Gyeonggi-do (KR); Yu Deuk KIM, Pyeongtaek-si Gyeonggi-do (KR); Jae Gab LIM, Pyeongtaek-si Gyeonggi-do (KR); Jeong Jun LEE, Pyeongtaek-si Gyeonggi-do (KR); Gun Hee CHO, Pyeongtaek-si Gyeonggi-do (KR)

(73) Assignee: WONIK IPS CO., LTD., Pyeongtaek-si Gyeonggi-do (KR)

(21) Appl. No.: 18/388,129

(22) Filed: Nov. 8, 2023

(30) Foreign Application Priority Data
Feb. 23, 2023 (KR) 10-2023-0024394

(51) Int. Cl. H01J 37/32; C23C 16/30; C23C 16/34; C23C 16/36; C23C 16/40; C23C 16/44; C23C 16/455; C23C 16/458; C23C 16/505; H01L 21/02

(52) U.S. Cl. CPC H01J 37/32853; C23C 16/308; C23C 16/345; C23C 16/36; C23C 16/402; C23C 16/4404; C23C 16/45536; C23C 16/4583; C23C 16/505; H01J 37/32715; H01J 37/32788; H01L 21/02126; H01L 21/0214; H01L 21/02164; H01L 21/0217; H01L 21/02274; H01L 21/0228; H01L 21/0234; H01J 2237/2007; H01J 2237/332

(57) ABSTRACT

A method of forming a thin film using a substrate processing apparatus includes placing the substrate on the electrostatic chuck, depositing the thin film on the substrate, transferring the substrate, and performing a hardening process. The depositing the thin film on the substrate applies a first DC power source to chuck the substrate, supplies a process gas and applies a first RF power source to form a first plasma to deposit the thin film on the substrate. The transferring the substrate transfers the substrate on which the thin film has been deposited outside the process chamber. The performing a hardening process applies a second DC power source, supplies a purge gas, and applies a second RF power source to form the plasma to harden a deposition film formed in an interior of the process chamber.

### CROSS-REFERENCES TO RELATED APPLICATION

The present application claims priority under 35 U.S.C. § 119(a) to Korean application number 10-2023-0024394 filed on Feb. 23, 2023, in the Korean Intellectual Property Office, which is incorporated herein by reference in its entirety as set forth in full.

### BACKGROUND

### 1. Technical Field

Various embodiments generally relate to a method for forming thin film and apparatus for processing substrate therefor. The method for forming thin film according to one exemplary embodiment can prevent process quality deterioration due to particle generation inside a process chamber in a continuous deposition process that repeatedly forms a thin film on a substrate. This effect can be achieved through a hardening process in which the sedimentary film inside the process chamber is treated with DC plasma. The DC plasma treatment can be performed by supplying DC power to an electrostatic chuck and forming plasma along with supplying a purge gas inside the process chamber.

### 2. Related Art

In general, a deposition process for depositing a thin film on a substrate utilizes a substrate processing apparatus. The substrate processing apparatus comprising a process chamber having a processing space, a gas injection unit for injecting gas into the process chamber, a gas supply unit for supplying gas to the gas injection unit, and a substrate seating unit such as an electrostatic chuck for placing the semiconductor substrate. The substrate processing apparatus may perform to deposit thin film using methods such as plasma enhanced chemical vapor deposition (PECVD) and plasma enhanced atomic layer deposition (PEALD).

The thin film deposition process as described above is performed by continuously supplying a substrate to be deposited in order to expand mass production. In the continuous thin film deposition process, a series of processes including placing the new substrate on the substrate seating unit, depositing the thin film, and transferring the substrate outside of the process chamber are continuously and repeatedly performed. In the continuous thin film deposition process described above, reaction products are generated during depositing the thin film, and the reaction products are deposited not only on the surface of the thin film but also on the inner surface of the process chamber to form a sedimentary film.

Afterwards, if the thin film deposition process is continuously performed the reaction product is delaminated from the sedimentary film and particles are generated. And the generated particles may cause a defect in the deposition process and adhere to the substrate, thereby reducing the yield of the semiconductor device. In the past, a cleaning process to clean the inside of the chamber after performing a certain amount of time or a certain number of thin film deposition processes was used to improve the particle problem. But when the cleaning cycle is shortened or, cleaning frequency is increased, it causes a decrease in unit per equipment hour (UPEH).

### SUMMARY

In an embodiment, an object is to provide a method for forming a thin film and substrate processing device that can prevent process defects due to particle generation and increase in unit per equipment hour (UPEH). Specifically, a method for forming a thin film using a substrate processing apparatus comprising a process chamber having a processing space for processing a substrate, an electrostatic chuck disposed inside the processing space and on which the substrate is placed, a gas injection unit for injecting gas onto the substrate, a constant power supply for applying DC power to cause the electrostatic chuck to chuck the substrate, and a plasma power supply for applying RF power to form a plasma in the process chamber may include placing the substrate on the electrostatic chuck; applying a first DC power source to chuck the substrate, supplying a process gas and applying a first RF power source to form a first plasma to deposit the thin film on the substrate; transferring the substrate on which the thin film has been deposited outside the process chamber; and performing a hardening process by applying a second DC power source, supplying a purge gas, and applying a second RF power source to form the plasma to harden a deposition film formed in an interior of the process chamber.

In an embodiment, a substrate processing apparatus may include a process chamber having a processing space for processing a substrate; an electrostatic chuck disposed inside the processing space and on which the substrate is placed; a gas injection unit for injecting gas onto the substrate; a constant power supply for applying DC power to cause the electrostatic chuck to chuck the substrate, a plasma power supply for applying RF power to form a plasma in the process chamber; and a control unit for controlling operation of the electrostatic chuck, the gas injection unit, the constant power supply, and the plasma power supply. The control unit may be configured to: apply a first DC power source to the electrostatic chuck; apply a first RF power source to the electrostatic chuck or the gas injection unit to perform a deposition process of depositing a thin film on the substrate in the processing space, and stop the application of the first DC power source and first RF power source; and take the substrate out of the processing space on which the thin film is deposited, supply purge gas to the processing space, and perform a DC plasma treatment to form the plasma by respective application of a second DC power source and a second RF power source to harden a deposition film formed in an interior of the process chamber.

In the substrate forming method according to one embodiment, a thin film is deposited on a substrate, and the substrate on which the thin film is deposited is transported to the outside of the process chamber. Then, a hardening process is performed to control and strengthen the cumulative thickness of the sedimentary film formed inside the process chamber using the DC (direct current) plasma treatment. The DC plasma treatment can be performed by supplying DC power to an electrostatic chuck and simultaneously forming plasma while supplying a purge gas. In various embodiments, the sedimentary film is strengthened in the process of continuously depositing a thin film through the DC plasma treatment, and particle generation from the deposited film is prevented, thereby preventing process defects and improving production per facility of the substrate processing device.

### BRIEF DESCRIPTION OF THE DRAWINGS

FIG. 1 is a timing diagram illustrating one example of a conventionally utilized thin film formation method.

FIG. 2 is a process diagram illustrating a method of forming a thin film according to an embodiment.

FIG. 3 is a timing diagram illustrating a method of forming a thin film according to an embodiment.

FIG. 4 is a conceptual diagram illustrating a substrate processing apparatus, according to an embodiment.

FIG. 5 shows the results of evaluating the change in refractive index (R.I.) of a coupon sample attached to the inside of the chamber after repeatedly depositing a silicon nitride film and a silicon oxide film, respectively, according to an example and a comparative example.

FIG. 6 shows the results of evaluating the number of particles generated by depositing a composite film comprising a silicon nitride film and a silicon oxide film on a substrate with 100 alternating repetitions per time (thickness basis: <4 μm) for a total of three times (thickness basis: >10 μm) according to an embodiment and a comparative example.

### DETAILED DESCRIPTION

FIG. 1 is a timing diagram illustrating one example of a conventionally utilized thin film formation method.

Referring to FIG. 1, conventionally, a substrate to be deposited is placed on an electrostatic chuck installed inside a process chamber, and a DC voltage is applied to the electrostatic chuck to chuck the substrate. Next, process gas is supplied to the top of the substrate and a plasma is formed to deposit a thin film on the top of the substrate. Next, the application of the DC voltage to the electrostatic chuck is stopped to de-chuck the substrate from the electrostatic chuck, and the substrate with the thin film deposited is transferred out of the process chamber. Next, a purge gas is supplied to the inside of the process chamber to perform the purge step. Next, a new substrate for depositing a thin film is placed back into the process chamber and a thin film is deposited on the top of the substrate and this thin film deposition process is performed continuously and repeatedly to mass produce semiconductor devices.

In this case, the thin film formation process as described above may be a process for forming a bulk type thin film with a thick thickness by continuously performing a single thin film deposition process. Or the thin film forming process as described above may be a process for forming a composite film by alternately depositing a first thin film and a second thin film. In other words, the thin film may be a composite film comprising a first thin film and a second thin film.

In the case of continuously forming a thin film through an in-situ process as described above, reaction products during the thin film deposition process are attached to the process chamber 110, the gas injection unit 130, etc. to form a deposition film on the surface. In this case, if a thin film with a thickness exceeding 10 μm or a thin film with a thickness of approximately 6 μm is deposited twice or more consecutively through the thin film deposition process as described above, even if a purge process is performed, the reaction products are delaminated from the deposited film and particles are generated, and the generated particles cause a decrease in the quality of the thin film to be deposited. The problem is that this phenomenon is accelerated in composite film deposition processes, where multiple thin films are deposited, or in film stack formation processes.

The thin film formation method according to various embodiments solves the problems of the existing technology as described above, and can prevent particle generation even when depositing a plurality of thin films in succession, thereby preventing deterioration of the quality of the thin film, thereby improving the output per unit of the substrate processing apparatus.

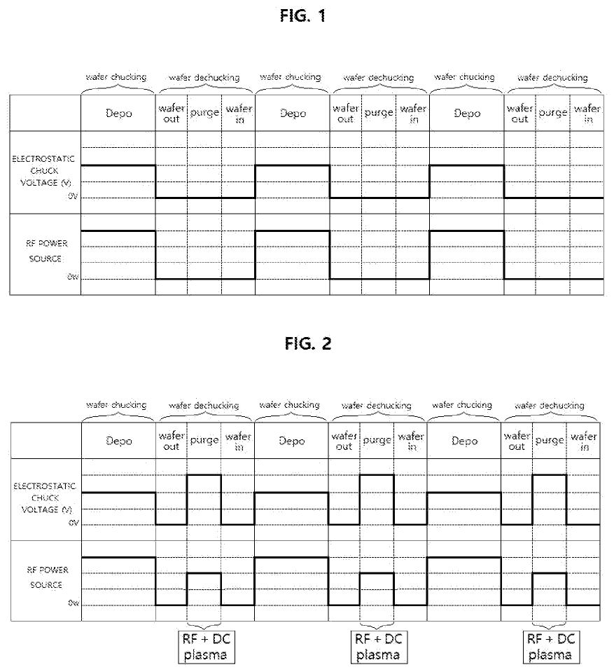

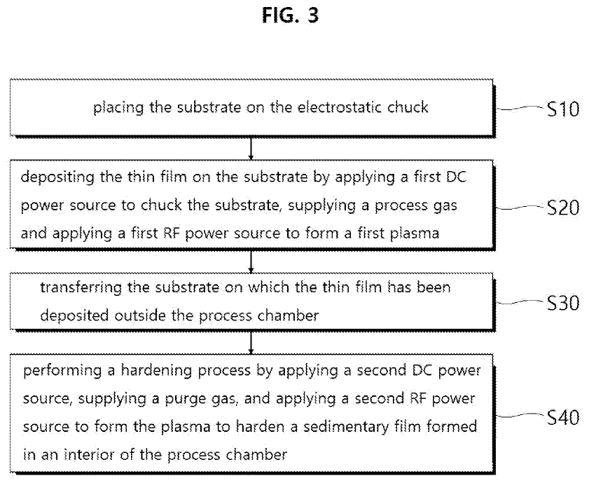

FIG. 2 is a timing diagram illustrating a method of forming a thin film according to an embodiment, and FIG. 3 is a process diagram illustrating a method of forming a thin film according to an embodiment.

Referring to FIGS. 2 and 3, a method of forming a thin film, according to an embodiment, may comprise placing a substrate on an electrostatic chuck S10; depositing a thin film on the substrate S20; transferring the substrate on which the thin film was deposited out of the process chamber S30; and performing a hardening process by a DC plasma treatment S40.

The method of forming the thin film can be performed using various types of conventional substrate processing apparatuses used for depositing thin films, such as plasma enhanced chemical vapor deposition (PECVD), plasma enhanced atomic layer deposition (PEALD), and the like.

Specifically, the substrate processing apparatus comprises a process chamber 110 having a processing space for processing a substrate, an electrostatic chuck 120 disposed inside the processing space and on which the substrate S is settled, and a gas injection unit 130 for injecting a process gas into the processing space, a constant power supply unit 140 for applying DC power to the electrostatic chuck 120, a plasma power supply unit 150 for applying RF power to form a plasma in the process chamber 110, and a control unit 160. The substrate processing apparatus will be described in more detail below, wherein each step of the thin film formation method according to an embodiment will be described in detail.

First, in the step S10, the new substrate for depositing a thin film is placed on the electrostatic chuck 120.

The substrate S may be any conventional variety of substrate used for depositing thin films. Specifically, the substrate S may have a plate shape and may be made of glass, silicon, or polymeric materials that can be electrostatically charged. Specifically, the substrate may be made of crystalline silicon, silicon oxide, silicon oxynitride, silicon nitride, strained silicon, silicon germanium, tungsten, titanium nitride, doped or undoped polysilicon, doped or undoped silicon wafers, patterned or unpatterned wafers, silicon on insulator (SOI), carbon doped silicon oxide, doped silicon, germanium, gallium arsenide, glass, sapphire, low k dielectrics, or mixtures thereof. The substrate may be the result of a semiconductor substrate on which a predetermined device has been formed, or may be a bare wafer.

Next, in the step S20, a first DC power is applied to the electrostatic chuck 120 to chuck the substrate S. And a process gas is supplied to the processing space. And a first RF power is applied to form a first plasma in the processing space to deposit a thin film on the substrate S.

In this step, thin films of various compositions generally deposited on a substrate may be deposited on the substrate S.

Specifically, the thin film may be a single-layer thin film comprising any one of a silicon oxide (SiO₂ layer), a silicon nitride (SiN layer), a silicon oxynitride (SiON layer), and a silicon oxycarbonitride (SiOCN layer). The process gas may include gases of various compositions generally supplied to form thin films such as those described above.

Alternatively, in this step a composite film may be formed on the substrate s. The composite film may be formed by alternately depositing a first thin film and a second thin film on the substrate S at least once. The first thin film and the second thin film formed as the composite film are not limited to the number of layers each, and may be stacked one layer each, and may have a structure in which a plurality of layers are stacked alternately.

Specifically, the first thin film and the second thin film may each be one of a silicon oxide (SiO₂ layer), a silicon nitride (SiN layer), a silicon oxynitride (SiON layer), and a silicon oxycarbonitride (SiOCN), and the first thin film and the second thin film may have different compositions. In particular, the first thin film may be a silicon oxide layer (SiO₂ layer) and the second thin film may be a silicon nitride layer (SiN layer).

Furthermore, in this step, a process gas may be supplied through the gas injection unit 130 for depositing a thin film on the substrate S, respectively. And a first RF power source including at least one of a high frequency (HF) power source and a very high frequency (VHF) power source may be applied to form a first plasma for depositing the thin film in the processing space.

In this step, a thin film having an average thickness of at least 1 to 100 μm, can be formed. Particularly in this step, the thin film with and average thickness of 10 to 20 μm, can be formed. In this step, particle generation due to delamination of the reaction product from the deposited film can be prevented even when forming a thin film of the above-mentioned thickness during the process of successively depositing the thin film.

Specifically, this step may be, but is not limited to, a process for depositing identical thin films in succession to form a bulk, thicker thin film.

Furthermore, this step may be a process for forming a composite film. The composite film may be formed by alternately depositing a first thin film and a second thin film at least once in a manner that alternately deposits a plurality of heterogeneous thin films on a top surface of the substrate.

In this case, the substrate may be formed with a deposition pattern comprising a plurality of pattern blocks on a top surface and a high aspect ratio space formed between the pattern blocks, respectively. In this step, a composite film may be formed in the high aspect ratio space by alternately depositing a first film and a second film at least once by alternately depositing a plurality of heterogeneous thin films on the top surface of the substrate to embed the high aspect ratio space with a composite film. The pattern blocks may be formed using a variety of conventional mold compositions utilized for forming composite film patterns on a substrate.

Next, in the step S30, the substrate S on which the thin film is deposited is transferring to the outside of the process chamber 110.

In this step, the application of the first DC voltage that carried out the deposition process of depositing the thin film on the substrate S is stopped, and the substrate S on which the thin film was deposited is de-chucked and separate from the electrostatic chuck 120 And then, the substrate separated form the electrostatic chuck is carried out of the process chamber 110. The substrate S may be carried out through various conventional methods.

Next, in the step S40, a hardening process is performed to harden a sedimentary film by DC plasma treatment. The DC plasma treatment is performed in the following manner. First, a second DC power source is applied to the electrostatic chuck 120, purge gas is supplied to the interior of the process chamber 110. Simultaneously, a second RF power source is applied to form a plasma to harden the deposit film formed on the interior of the process chamber 110 and on the surface of the gas injection unit 130.

In the step S40, ions are formed by plasma formed by applying the second RF power. Additionally, positive voltage DC power is applied to the electrostatic chuck 120. As a result, the gas injection unit side becomes relatively negatively charged, and the movement of positive charge toward the gas injection unit 130 is accelerated. Accordingly, the density of the sedimentary film formed on the inner surface of the process chamber is greatly increased and strengthened, the reaction products are stabilized to prevent particle generation from the sedimentary film formed on the inner surface of the process chamber. And the margin of the deposition film is secured during the process of taking out and settling the substrate. Accordingly, even when a thick deposition film is formed due to excessive deposition of reaction products on the surface of the process chamber 110 and the gas injection unit 130, the reaction products are not easily delaminated from the formed deposition film.

To this end, the second DC power source applied in this step may be the same as the first DC power source applied in the deposition step S20, or the second DC power source may be controlled so that the second DC power source has a higher voltage than the first DC power source. In particular, the second DC power source may be controlled to have a higher voltage than the first DC power source.

The second DC power source as described above may be configured to apply a positive voltage of 100 to 1,000 volts.

Further, in this step, the hardening treatment may be performed by applying a second RF power source comprising at least one of a high frequency (HF) power source and a very high frequency (VHF) power source to form a second plasma.

The second RF power source may be controlled to have the same or lower power than the first RF power source. In particular, the second RF power source may be controlled to have a lower power than the first RF power source. Specifically, the second RF power source may provide a power of 50 to 500 watts.

As described above, the voltage and power of the second DC power source and the second RF power source can be adjusted relative to the first DC power source and the first RF power source, respectively, to further strengthen the deposition film.

Furthermore, in this step, the hardening treatment can be performed for 5 to 180 seconds. After performing the hardening process (i.e. performing the DC plasma treatment) for such a time, a new substrate to be deposited for thin film deposition can be settled on the electrostatic chuck and a thin film deposition process can be performed. In particular, the hardening treatment can optionally adjust the treatment time according to conditions.

The purge gas may utilize a variety of conventional inert gases, such as argon (Ar) gas, nitrogen (N₂) gas, helium (He) gas, neon (Ne) gas, or mixtures thereof.

In this step, after performing the hardening treatment step S40, and then the deposition step (wafer in) in which a new substrate to be deposited for thin film deposition is placed on the electrostatic chuck 120 is performed again, and the deposition process can be performed successively.

This step may also comprise hardening the sedimentary film, followed by a step of stabilizing and stopping the application of the second DC power source and the second RF power source, and then settling the new substrate to be deposited on the electrostatic chuck.

The method of forming a thin film according to the above-described embodiment can control and harden the cumulative thickness of the sedimentary film formed inside the process chamber by supplying DC power to the electrostatic chamber and performing DC plasma treatment to form a plasma with the supply of purge gas while the substrate on which the thin film is deposited is transferred out of the process chamber. Thus, it is possible to prevent the occurrence of particles from the sedimentary film formed on the inner surface of the process chamber in the process of depositing thin films continuously, thereby preventing process failures, and thus improving the output per unit of the substrate processing apparatus.

In particular, the method of forming a thin film according to various embodiment is applicable to a bulk film deposition process in which the same thin film is deposited continuously, a composite film deposition process in which a plurality of thin films with different compositions are deposited alternately, and a process in which a high aspect ratio space is embedded with a composite film, and as the number of layers increases, a higher utilization and higher quality thin film can be formed.

Accordingly, the substrate may have a structure having a deposition pattern formed thereon, including a plurality of pattern blocks on the top and a high aspect ratio space formed between the pattern blocks, and the depositing the thin film may alternately deposit a first thin film and a second thin film at least once to form a composite film embedded in the high aspect ratio space.

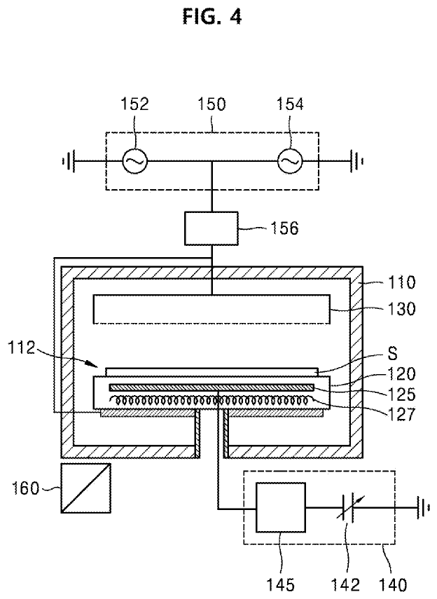

FIG. 4 is a conceptual diagram illustrating a substrate processing apparatus according to an embodiment. Referring to FIG. 4, a substrate processing apparatus according to an embodiment may have a structure including a process chamber 110; an electrostatic chuck 120; a gas injection unit 130; a constant power supply 140; a plasma power supply 150; and a control unit 160.

The process chamber 110 has a structure comprising a processing space 112 for processing a substrate. Specifically, the process chamber 110 may define the processing space 112 internally. For example, the process chamber 110 may be configured to be gas-tight and may be connected to a vacuum chamber (not shown) via an exhaust port to exhaust process gases within the processing space 112 and to regulate a vacuum within the processing space 112. The process chamber 110 may be provided in a variety of shapes, and may include, for example, sidewalls defining the processing space 112 and a lid portion located on top of the sidewalls.

The electrostatic chuck 120 is disposed inside the processing space 112 and provides a space for the substrate S to rest.

Specifically, the electrostatic chuck 120 may be installed in the process chamber 110 opposite the gas injection unit 130, on top of which the substrate S may be resting, and may provide a chucking force to the substrate to secure the substrate. To this end, the electrostatic chuck 120 may include electrostatic electrode 125 for applying an electrostatic force to the substrate S and securing it thereon.

Further, the electrostatic chuck 120 may include a heater 127 for heating the substrate S, and may further include a separate power supply (not shown) for powering the heater 127.

The shape of the electrostatic chuck 120 generally corresponds to the shape of the substrate S, but may be provided in a variety of shapes, including, but not limited to, being larger than the substrate S to allow the substrate S to be held securely. Furthermore, the electrostatic chuck 120 may be connected to an external motor (not shown) for raising and lowering. In this case, a bellows tube (not shown) may be connected for maintaining air tightness.

Furthermore, because the electrostatic chuck 120 is configured to hold a substrate S thereon, it may be referred to as a substrate holder, substrate support, susceptor, or the like.

The gas injection unit 130 serves to inject process gas into the processing space. Specifically, the gas injection unit 130 may be installed in the process chamber 110 to supply process gas supplied from outside of the process chamber 110 into the processing space 112. The gas injection unit 130 may be installed at the top of the process chamber 110, opposite the electrostatic chuck 120, to inject process gas onto the substrate S resting on the electrostatic chuck 120. The gas injection unit 130 may include at least one inlet hole formed in a top or side portion to receive process gas from an external source, and a plurality of injection holes formed in a downwardly facing direction facing the substrate S to inject process gas onto the substrate.

Further, the gas injection unit 130 may have various shapes, such as a shower head shape, a nozzle shape, and the like. If the gas injection unit 130 is in the form of a shower head, the gas injection unit 130 may be coupled to the process chamber 110 in a manner that covers an upper portion of the process chamber 110. For example, the gas injection unit 130 may be coupled to a sidewall portion of the process chamber 110 in the form of a cover.

The constant power supply 140 serves to apply DC power for the electrostatic chuck 120 to chuck the substrate S. The constant power supply 140 may include a DC power source 142 to supply DC power to the electrostatic electrode 125. The DC power source 142 may be installed such that one end is connected to ground and the other end is electrically connected to the electrostatic electrode 125 via node n1 to supply DC power.

The constant power supply 140 may further include a DC filter 145 disposed between the electrostatic electrode 125 and the DC power source 142 to block RF current from entering the DC power source 142 via the electrostatic electrode 125. The DC filter 145 may be configured in various forms to block RF current while allowing DC current to pass through.

The plasma power supply 150 serves to apply RF power to form a plasma in the process chamber 110. Specifically, the plasma power supply 150 may include at least one radio frequency (RF) power source to apply at least one RF power to the process chamber 110 to form a plasma atmosphere inside the process chamber 110. For example, the plasma power supply 150 may be connected to apply RF power to the gas injection unit 130. In this case, the gas injection unit 130 may be referred to as a power supply electrode or a top electrode.

In another example, the plasma power supply 150 may be connected to a bias electrode 125, forming the electrostatic chuck 120, disposed at the bottom of the electrostatic chuck 120 to apply RF power to the electrostatic chuck 120. In this case, the electrostatic chuck 120 may be referred to as the bottom electrode.

The plasma power supply 150 may include an impedance matching unit 156 disposed between the plasma power supply 150 and the gas injection unit 130 for impedance matching between the RF power source and the process chamber 110.

The plasma power supply 150 may include at least one RF power source, and the RF power source may include a first RF power source 152 in a first frequency band and a second RF power source 154 in a second frequency band greater than the first frequency band for controlling the plasma environment according to process conditions. The dual-frequency power source comprising the first RF power source 152 and the second RF power source 154 may be configured to vary the frequency bands depending on process conditions or process steps to provide precise control of the process.

The control unit 160 serves to control the operation of the electrostatic chuck 120, gas injection unit 130, constant power supply 140, and plasma power supply 150.

In particular, the control unit 160 performs a deposition step of depositing a thin film on the substrate S inside the process chamber 110 and stops applying the first DC power source and the first RF power source. Subsequently, the control unit 160 may control the substrate S on which the thin film has been deposited to be taken out of the process chamber 110 and then apply a second DC power source to the electrostatic chuck 120 and apply a second RF power source to form a plasma to perform a hardening treatment of the deposited film formed on the interior of the process chamber 110 and on the surface of the gas injection unit 130.

Furthermore, the control unit 160 may perform a hardening treatment of the deposited film as described above, and then discontinue the application of the second DC power source and second RF power source, settle the substrate on the electrostatic chuck 120, and control the application of the first DC power source and first RF power source to chuck the substrate for deposition of a new thin film, supply process gas, and form a plasma to deposit the thin film.

Hereinafter, various embodiments will be described in more detail. The embodiments shown are only specific examples of the invention and are not intended to limit the technical scope of the invention.

### Example

First, coupon samples of nitride and oxide films were attached to the lower surface of the showerhead, a gas injection unit installed inside the process chamber. Next, the substrate was placed on an electrostatic chuck, the electrostatic chuck voltage was applied to chuck the substrate, and silicon nitride and silicon oxide films were sequentially deposited on the substrate. Next, the substrate on which the thin film was deposited was de-chucked and, separated from the electrostatic chuck, and transferred to the outside of the process chamber and a new substrate for depositing the thin film was deposited on the electrostatic chuck. During the process of transferring the substrate and depositing the new substrate, the substrate was de-chucked from the electrostatic chuck by stopping the application of the electrostatic chuck voltage and RF power to remove the substrate, and during the process of transferring the substrate, a DC power source with a higher power than the chucking force applied to the substrate to perform the thin film deposition process and a RF power source with a lower current were applied, and a plasma was formed to perform the hardening treatment (i.e. the DC plasma treatment). Then, during the process of placing the substrate on the electrostatic chuck, the application of the electrostatic chuck voltage and RF power was stopped.

### Comparative Example

First, nitride and oxide coupon samples were attached to the lower surface of a showerhead installed inside the process chamber.

Next, the thin film deposition process was performed in the same way as in the example, and the thin film deposition process was performed continuously without applying DC power and RF power during the substrate removal and deposition process.

### Experiment Example

### (1) Evaluate Refractive Index

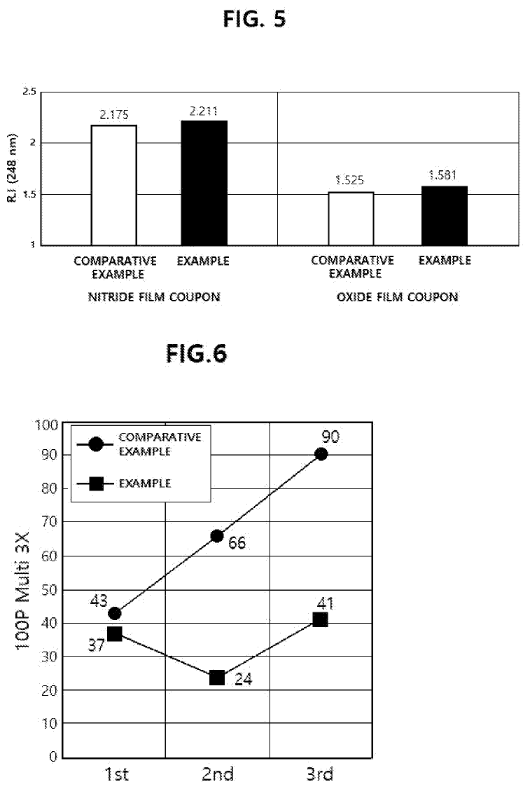

To evaluate the effect of performing the thin film deposition process according to the example and comparative example on the strengthening of the film, the effect on the refractive index of the thin film of the coupon sample was evaluated, and the results are shown in FIG. 5.

FIG. 5 shows the results of evaluating the change in the reflective index (R.I.) of a coupon sample attached to the inside of the chamber after repeatedly depositing a silicon nitride film and a silicon oxide film, respectively, using a method according to an example and a comparative example.

As shown in FIG. 5, it was confirmed that the refractive index tends to increase when a thin film is formed by the method according to the example compared to the case of the comparative example, respectively, and this increase in refractive index means that the thickness of the film increases, and the density of the deposited film such as an oxide film or a nitride film formed on the gas injection unit increases.

### (2) Evaluate Particle Generation

The effect of performing the thin film deposition process according to the method of the example and comparative example on particle generation was evaluated, and the results are shown in FIG. 6.

FIG. 6 shows the results of evaluating the number of particles generated by alternating deposition of a silicon nitride film and a silicon oxide film on a substrate by a method according to the example and comparative example, for a total of three deposition cycles (thickness basis: >10 μm) with 100 alternating cycles per cycle (thickness basis: <4 μm).

As shown in FIG. 6, when a thin film is formed by the method according to the comparative example, it can be confirmed that the number of particles generated tends to increase rapidly as the composite film deposition process is repeated, but when a thin film is formed by the method according to the example, it can be confirmed that a certain number of particles are formed, and it can be confirmed that the particles can be improved by DC plasma treatment in which DC power is supplied to the electrostatic chuck and a plasma is formed with the supply of purge gas.

### (3) Evaluate Unit Per Equipment Hour (UPEH) Production

The impact of the method according to the example and comparative example on the output per unit was evaluated when performing the thin film deposition process. At this time, the evaluation was performed assuming that one DC plasma treatment was performed for a maximum of 60 seconds, and that the DC plasma treatment was performed twice.

As a result, it was determined that in the process of continuously depositing thin films, a total of 20 sheets were deposited in the comparative example, while a total of 24 sheets were deposited in the example, giving a total of 4 additional sheets of thin film deposition effect, which can significantly improve the output per unit.

From the above results, it can be seen that by utilizing the thin film formation method according to the embodiment, it is possible to increase the density of the deposited film by supplying DC power to the electrostatic chuck in a purge process that supplies purge gas and proceeding with DC plasma treatment that forms a plasma with the supply of purge gas, and it is possible to prevent the generation of particles from the deposited film, thereby greatly improving the output per unit of the substrate processing apparatus.

In particular, the method of forming a thin film such as the embodiment is applicable not only to the mold stacking process, but also to the bulk film deposition process in which the same thin film is deposited continuously, the composite film deposition process in which a plurality of thin films with different compositions are deposited alternately, and the process in which a high aspect ratio space is embedded in a composite film, and it is judged that it is possible to form a high-quality thin film with higher utilization as the number of layers increases.

While certain embodiments have been described above, it will be understood to those skilled in the art that the embodiments described are by way of example only. Accordingly, the method for forming thin film and apparatus for processing substrate therefor should not be limited based on the described embodiments. Rather, the method for forming thin film and apparatus for processing substrate therefor described herein should only be limited in light of the claims that follow when taken in conjunction with the above description and accompanying drawings.

What is claimed is:

1. A method of forming a thin film using a substrate processing apparatus comprising a process chamber having a processing space for processing a substrate, an electrostatic chuck disposed inside the processing space and on which the substrate is placed, a gas injection unit for injecting gas onto the substrate, a constant power supply for applying DC power to cause the electrostatic chuck to chuck the substrate, and a plasma power supply for applying RF power to form a plasma in the process chamber, the method including:
placing the substrate on the electrostatic chuck;
depositing the thin film on the substrate by applying a first DC power source to chuck the substrate, supplying a process gas and applying a first RF power source to form a first plasma;
transferring the substrate on which the thin film has been deposited outside the process chamber; and
performing a hardening process by applying a second DC power source, supplying a purge gas, and applying a second RF power source to form the plasma to harden a sedimentary film formed in an interior of the process chamber.

2. The method of claim 1, wherein depositing the thin film includes depositing the thin film with a thickness of at least 10 to 20 μm.

3. The method of claim 1, wherein depositing the thin film includes depositing a first thin film and a second thin film on the substrate at least once to form a composite film on the substrate.

4. The method of claim 3, wherein the first thin film and the second thin film are each one of a silicon oxide layer (SiO₂ layer), a silicon nitride layer (SiN layer), a silicon oxynitride layer (SiON layer), and a silicon carbonitride layer (SiOCN), and the first thin film and the second thin film have different compositions.

5. The method of claim 3, wherein the first thin film is a silicon oxide layer (SiO₂ layer) and the second thin film is a silicon nitride layer (SiN layer).

6. The method of claim 1, wherein depositing the thin film includes supplying at least one of an HF power source and a VHF power source to form the first plasma for depositing the thin film.

7. The method of claim 1, wherein the second DC power source has a higher voltage than the first DC power source.

8. The method of claim 1, wherein the second DC power source is a positive voltage of 100 to 1,000 volts.

9. The method of claim 1, wherein the second RF power source has a lower power than the first RF power source.

10. The method of claim 1, wherein the second RF power source has a power of 50 to 500 watts.

11. The method of claim 1, wherein performing the hardening process is performed for 5 to 180 seconds.

12. The method of claim 1, wherein performing the hardening process further includes stabilizing in which the deposition film is subjected to a hardening treatment and then the applying of the second DC power source and second RF power source is discontinued.

13. The method of claim 1, wherein depositing the thin film includes forming a composite film formed by alternately depositing a first thin film and a second thin film at least once by alternately depositing a plurality of heterogeneous thin films on an upper portion of the substrate.

14. The method of claim 1, wherein a deposition pattern comprising a plurality of pattern blocks and a high aspect ratio space formed between the pattern blocks, respectively, is formed on the substrate.

15. A substrate processing apparatus comprising:
a process chamber having a processing space for processing a substrate; an electrostatic chuck disposed inside the processing space and on which the substrate is placed; a gas injection unit for injecting gas onto the substrate; a constant power supply for applying DC power to cause the electrostatic chuck to chuck the substrate, a plasma power supply for applying RF power to form a plasma in the process chamber;
and a control unit for controlling operation of the electrostatic chuck, the gas injection unit, the constant power supply, and the plasma power supply,
wherein the control unit is configured to:
apply a first DC power source to the electrostatic chuck;
apply a first RF power source to the electrostatic chuck or the gas injection unit to perform depositing a thin film on the substrate in the processing space, and stop the application of the first DC power source and first RF power source; and
transfer the substrate out of the processing space on which the thin film is deposited, supply purge gas to the processing space, and perform a hardening process to form the plasma by respective application of a second DC power source and a second RF power source to harden a deposition film formed in an interior of the process chamber.

16. The substrate processing apparatus of claim 15, wherein the control unit controls stopping the application of the second DC power source and the second RF power source after performing the gardening process and then controls placing a new substrate on the electrostatic chuck, and depositing a new thin film on the substrate and transferring the substrate out of the process space.
